(19) United States
(12) Patent Application Publication
(10) Pub. No.: US 2016/0181287 A1
(43) Pub. Date: Jun. 23, 2016

(54) FLEXIBLE SUBSTRATE, MANUFACTURING METHOD THEREOF AND FLEXIBLE DISPLAY DEVICE

(71) Applicant: BOE Technology Group Co., Ltd., Beijing (CN)

(72) Inventors: Wenbo LI, Beijing (CN); Guanghui LIU, Beijing (CN)

(73) Assignee: BOE TECHNOLOGY GROUP CO., LTD., Beijing (CN)

(21) Appl. No.: 14/435,524

(22) PCT Filed: Dec. 5, 2014
(86) PCT No.: PCT/CN2014/093175

§ 371 Date: Apr. 14, 2015

(30) Foreign Application Priority Data
Jun. 3, 2014 (CN) 201410242864.4

(51) Int. Cl. H01L 27/12; H01L 27/32; H01L 51/56; H01L 51/52; H01L 51/00

(52) U.S. Cl. CPC H01L 27/1218; H01L 51/5203; H01L 27/1248; H01L 51/0097; H01L 51/56; H01L 27/1259; H01L 27/124; H01L 27/3276; H01L 2251/5338; H01L 2227/323; H01L 27/3262

(57) ABSTRACT

A flexible substrate, a manufacturing method thereof and a flexible display device are disclosed. The flexible substrate includes a display panel region and a flexible printed circuit board (FPC) region. The display panel region includes a flexible base (21), a gate electrode (22), a gate insulating layer (23), an active layer (24), a source electrode (25), a drain electrode (26), a passivation layer (27) and a pixel electrode (28). The pixel electrode (28) is electrically connected with the drain electrode (26) through an opening in the passivation layer (27). The FPC region includes a lead structure which is formed on the flexible base (21) and made from a material including at least one or a combination of more selected from a material for preparing the gate electrode (22), a material for preparing the source electrode (25) and the drain electrode (26), and a material for preparing the pixel electrode (28).

### TECHNICAL FIELD

At least one embodiment of the present invention relates to a flexible substrate, a manufacturing method thereof and a flexible display device.

### BACKGROUND

Integration is an important development trend of display technology in the future and can effectively promote display devices to advance towards higher resolution, lighter weightiness and thinner profile, and more power-saving. With the enhanced electron mobility and the finer critical width of thin-film transistor (TFT) devices, the integration of scanning driving circuits, data driving circuits, timers (Tcon), memories, central processing units (CPUs) and the like on the substrate will become possible.

### SUMMARY

Embodiments of the present invention provide a flexible substrate, a manufacturing method thereof and a flexible display device to solve the problem of integrating an array substrate and a flexible printed circuit (FPC) on the same substrate.

At least one embodiment of the present invention provides a flexible substrate, which comprises a display panel region and a flexible printed circuit board (FPC) region. The display panel region includes a flexible base and a gate electrode, a gate insulating layer, an active layer, source/drain electrodes, a passivation layer and a pixel electrode formed on the flexible base. The pixel electrode is electrically connected with the drain electrode through an opening in the passivation layer. The FPC region includes a lead structure which is formed on the flexible base and made from materials including at least one or a combination of more selected from the material for preparing the gate electrode, the material for preparing the source/drain electrodes, and the material for preparing the pixel electrode.

At least one embodiment of the present invention further provides a method for manufacturing a flexible substrate, which comprises: forming a gate electrode, a gate insulating layer, an active layer, source/drain electrodes and a passivation layer on a flexible base, and forming an opening in the passivation layer to expose at least one part of the drain electrode; and forming a pixel electrode on the passivation layer. In the method, a lead structure is formed in an FPC region at the same time when at least one step among the step of forming the gate electrode, the step of forming the source/drain electrodes and the step of forming the pixel electrode is performed.

At least one embodiment of the present invention further provides a flexible display device, which comprises the foregoing flexible substrate.

### BRIEF DESCRIPTION OF THE DRAWINGS

Simple description will be given below to the accompanying drawings of the embodiments to provide a more clear understanding of the technical proposals of the embodiments of the present invention. Obviously, the drawings described below only involve some embodiments of the present invention but are not intended to limit the present invention.

FIG. 1 is a schematic structural view of an FPC provided by an embodiment of the present invention;

FIG. 2 is a schematic diagram of a flexible substrate provided by an embodiment of the present invention;

FIGS. 3A to 3D are schematic diagrams of a method for manufacturing a flexible substrate, provided by an embodiment of the present invention;

FIG. 4 is a schematic diagram of a flexible substrate provided by another embodiment of the present invention;

FIGS. 5A to 5D are schematic diagrams of a method for manufacturing a flexible substrate, provided by an embodiment of the present invention; and

FIGS. 6A to 6B are schematic diagrams of the flexible substrate provided by an embodiment of the present invention.

### DETAILED DESCRIPTION

For more clear understanding of the objectives, technical proposals and advantages of the embodiments of the present invention, clear and complete description will be given below to the technical proposals of the embodiments of the present invention with reference to the accompanying drawings of the embodiments of the present invention. Obviously, the preferred embodiments are only partial embodiments of the present invention but not all the embodiments. All the other embodiments obtained by those skilled in the art without creative efforts on the basis of the embodiments of the present invention illustrated shall fall within the scope of protection of the present invention.

The existing forms of driver integrated circuits (ICs) on a display device mainly includes: tape automated bonding (TAB), chip on board (COB), chip on glass (COG), chip on film (COF), chip in array (CIA), etc. TAB refers to fixing an IC with the package mode of tape carrier package (TCP) on a liquid crystal display (LCD) and a printed circuit board (PCB) respectively by an anisotropic conductive adhesive; COB refers to directly bonding a chip on a PCB; COG refers to directly bonding a chip on glass, in which the mounting mode has the advantages of greatly reducing the volume of the entire LCD module, easy to realize mass production and applicable to LCDs for consumer electronics products of portable electronics products such as mobile phones and personal digital assistants (PDAs); COF refers to directly mounting a chip on an FPC, which the connection mode has high integration and peripheral elements may be mounted on the FPC together with the IC; and CIA refers to the direct arrangement of a chip circuit on an array substrate. The relatively more successful application is to directly integrate a gate electrode IC on a display. As for the direct arrangement of a data IC on glass, the technological difficulty is large. Currently, mobile phone products in mass production generally adopt COG mode.

The inventors of the application in research have noted that: the processes such as TAB, COB, COG, COF and CIA all require the pin alignment and bonding processes of ICs or FPCs, which results in the problems of alignment error, poor contact and the like and hence affects the yield of products.

FPC has the advantages of flexibility, small size and light weight, functions as conduction and bridge in electronic products, and allows the electronic products to have better performances and smaller size. With the great attention of people on flexible display, integrated production is a development trend in the production of display panels, and an array substrate and a peripheral FPC must be formed on the same substrate at the same time to reduce the manufacturing costs.

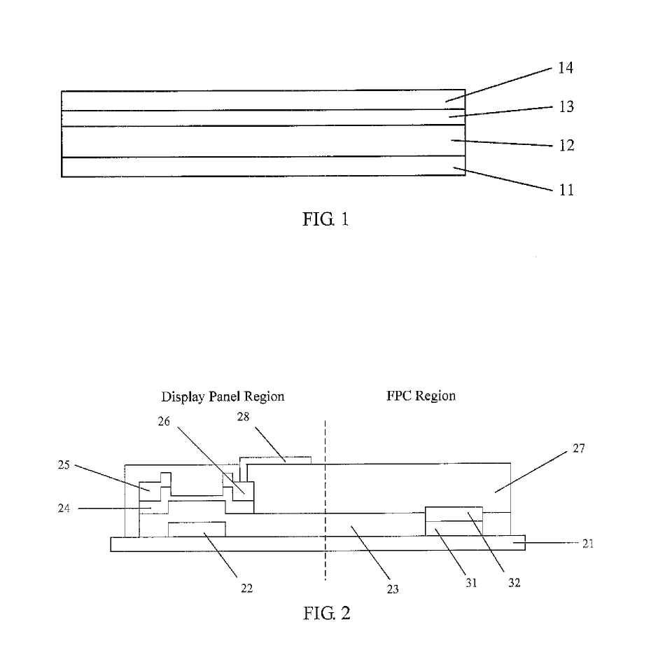

FIG. 1 is a schematic structural view of an FPC provided by an embodiment of the present invention. After the exposure, development and etching of the FPC, a conductive path can be formed on a flexible substrate. The FPC includes a flexible base 11, a conductive layer 12, an adhesive layer 13 and an overcoat substrate 14 that are stacked successively. The flexible base 11 and the overcoat substrate 14 may be made from the same material which, for instance, may be PI or PET. PI has higher price but better flame resistance property. PET has lower price but poor heat resistance property. Therefore, PI material is mostly selected in the case of welding requirement.

At least one embodiment of the present invention provides a flexible substrate, which comprises a display panel region and an FPC region. The FPC region includes a flexible base and a gate electrode, a gate insulating layer, an active layer, source/drain electrodes, a passivation layer and a pixel electrode formed on the flexible base. The pixel electrode is electrically connected with the drain electrode through an opening in the passivation layer. The FPC region includes a lead structure which is formed on the flexible base and made from a material including at least one or a combination of more selected from the material for preparing the gate electrode, the material for preparing the source/drain electrodes, and the material for preparing the pixel electrode.

In the flexible substrate provided by the embodiment of the present invention, the structure of the FPC region is, for instance, similar to the structure of the FPC as shown in FIG. 1 in which a conductive structure is disposed in a conductive layer 12 as shown in FIG. 1.

In the flexible substrate provided by at least one embodiment, the gate electrode is formed on the flexible base; and the gate insulating layer may be formed on the gate electrode or may be formed between the gate electrode and the flexible base. That is to say, the TFT disposed in the display panel region may adopt a bottom-gate type or a top-gate type.

In the flexible substrate provided by at least one embodiment, when the gate insulating layer is formed on the gate electrode, the active layer is formed on the gate insulating layer; and when the gate insulating layer is formed between the gate electrode and the flexible base, the active layer is formed between the gate insulating layer and the flexible base. Moreover, the source/drain electrodes are formed on the active layer or make contact with the bottom of the active layer; and the passivation layer is formed on the source/drain electrodes. That is to say, the active layer and the source/drain electrodes disposed in the TFT of the display panel region may adopt top contact or bottom contact.

At least one embodiment of the present invention provides a method for manufacturing a flexible substrate, which comprises: forming a gate electrode, a gate insulating layer, an active layer, source/drain electrodes, a passivation layer and a pixel electrode, that are in a display panel region, on a flexible base. In the method, the passivation layer is provided with an opening to expose at least one part of the drain electrode; the pixel electrode is formed on the passivation layer; and a lead structure is formed in an FPC region at the same time when at least one step, among forming the gate electrode, forming the source/drain electrodes and forming the pixel electrode, is performed.

In the method provided by the embodiment of the present invention, a TFT disposed in the display panel region may adopt a bottom-gate type or a top-gate type, and the active layer and the source/drain electrodes in the TFT may adopt top-contact or bottom-contact. In one embodiment, taking the bottom-gate top-contact type as an example, the method comprises: forming a gate metal layer on the flexible base, patterning the gate metal layer, and forming the gate electrode in the display panel region; forming the gate insulating layer and the active layer on the gate electrode in sequence, and patterning the gate insulating layer and the active layer; forming the source/drain electrodes on the active layer; and forming the passivation layer on the source/drain electrodes.

In the method provided by at least one embodiment, a first conductive layer of the lead structure is formed in the FPC region at the same time when the gate electrode is formed; and a second conductive layer of the lead structure is formed at the same time when the source/drain electrodes are formed. On this basis, in one example, the method further comprises the step of forming a third conductive layer of the lead structure at the same time when the pixel electrode is formed.

Description will be given below with respect to the flexible substrate and the manufacturing method thereof in the following embodiments by taking the case that the TFT in the flexible substrate as shown in FIG. 2 adopts bottom-gate type and the active layer and the source/drain electrodes adopt top contact as an example.

FIG. 2 is a schematic diagram of a flexible substrate provided by an embodiment of the present invention. As illustrated in FIG. 2, an array substrate of a display panel and an FPC substrate share the same flexible base 21 which is made from a material including but not limited to flexible PI or PET material. A TFT structure is formed in a display panel region of the base 21. In the TFT structure, a gate electrode 22 is formed on the base 21; a gate insulating layer 23 is formed on the gate electrode 22 and covers the gate electrode 22; an active layer 24 is formed on the gate insulating layer 23; a source electrode 25 and a drain electrode 26 are formed on the active layer 24; a passivation layer 27 covers the source electrode 25 and the drain electrode 26; and a pixel electrode 28 is electrically connected with the drain electrode 26 through an opening in the passivation layer 27. In an FPC region of the base 21, a lead structure is, for instance, formed in an opening on the gate insulating layer 23. For instance, the lead structure includes a first conductive layer 31 and a second conductive layer 32. The first conductive layer 31 is made from the material for preparing the gate electrode of the TFT. The second conductive layer 32 is made from the material for preparing the source/drain electrodes of the TFT. For instance, the passivation layer 27 of the TFT is prepared to be an insulating protective layer of the lead structure. As for areas such as circuit pins on the FPC, the passivation layer is removed to expose the lead structure. FIG. 2 is only an example. The lead structure in the embodiment of the present invention is not limited thereto and may be made from a material including at least one or a combination of more selected from the material for preparing the gate electrode of the TFT, the material for preparing the source/drain electrodes of the TFT, and the material for preparing the pixel electrode of the TFT. The lead structure is made from a material including at least one or a combination of more selected from Mo, Fe, Ag, Cu, Al, carbon nanotube, graphene, etc. The embodiment of the present invention is not limited thereto. But a material with low resistivity, e.g., metal Cu, carbon nanotube and graphene, are preferably selected.

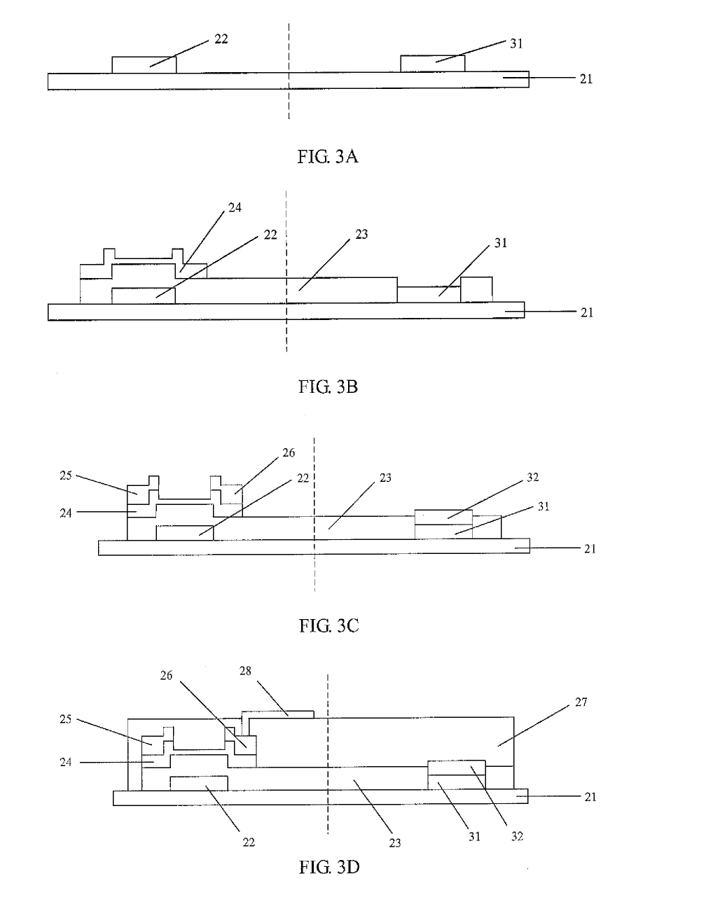

FIGS. 3A to 3D are schematic diagrams of the method for manufacturing the flexible substrate, provided by an embodiment of the present invention. Description will be given below by still taking the case that a superimposed layer of the gate metal layer and the source/drain metal layer of the TFT is taken as the lead structure of the FPC as an example.

As illustrated in FIG. 3A, the gate metal layer is formed on the flexible base 21 by sputtering or the like way; the gate electrode 22 is formed in the display panel region by a photolithographic etching process; and meanwhile, the first conductive layer 31 is formed in the FPC region. The distribution layout of the first conductive layer 31 is determined according to the requirement of an IC.

As illustrated in FIG. 3B, the gate insulating layer 23 and the active layer 24 are formed on the flexible base 21 by chemical vapor deposition (CVD), sputtering or the like way, and the active layer 24 and partial gate insulating layer 23 in the FPC region are removed to expose the first conductive layer 31.

As illustrated in FIG. 3C, the source/drain metal layer is formed by sputtering or the like way; the source electrode 25 and the drain electrode 26 are formed in the display panel region by a photolithographic etching process; and the second conductive layer 32 is formed in the FPC region and combined with the second conductive layer 32 to form superimposed effect to increase the lead thickness and reduce the resistance.

As illustrated in FIG. 3D, the passivation layer 27 is formed by CVD or the like way; a through hole is formed in the passivation layer 27 of the display panel region to expose the drain electrode 26; and the pixel electrode 28 is formed by processes such as sputtering and etching or the like way. Through-hole etching may also be selectively performed in the FPC region to provide convenience for the subsequent welding of chip leads.

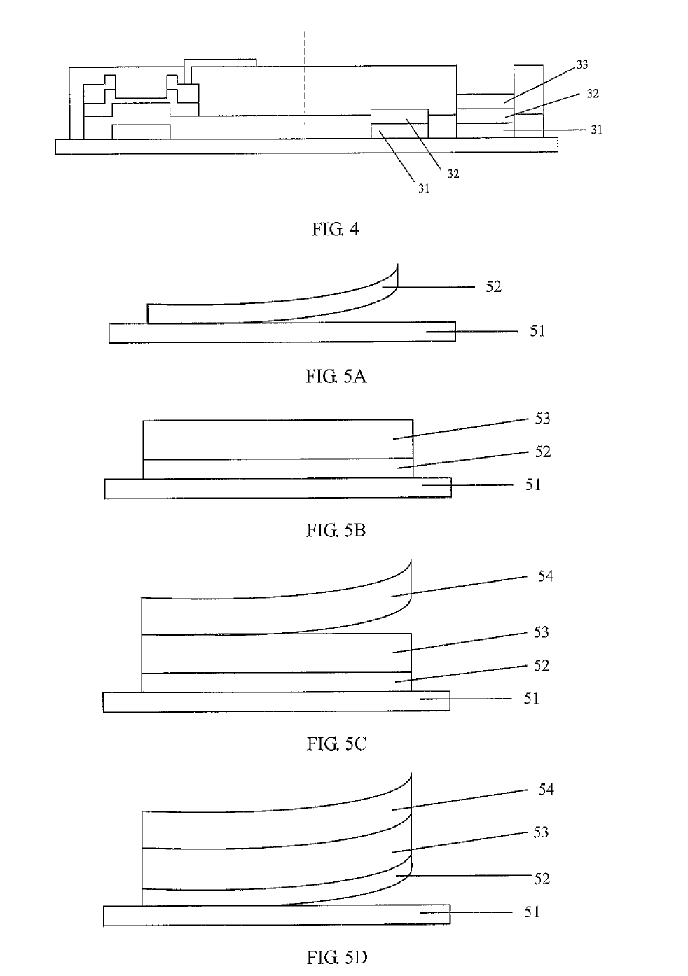

In the flexible substrate provided by at least one embodiment, the lead structure may further include a third conductive layer. The third conductive layer is, for instance, made from the material for preparing the pixel electrode. FIG. 4 is a schematic diagram of a flexible substrate provided by another embodiment of the present invention. As illustrated in FIG. 4, the lead structure in the FPC region includes a first conductive layer 31 formed in synchronization with the gate electrode, a second conductive layer 32 formed in synchronization with the source/drain electrodes, and a third conductive layer 33 formed in synchronization with the pixel electrode. The third conductive layer 33 is exposed to the outside to provide convenience for the subsequent welding of chip leads. Meanwhile, as the third conductive layer 33 and the pixel electrode are formed synchronously and made from a material such as indium tin oxide (ITO), the oxidization of leads can be prevented.

FIGS. 5A to 5D are schematic diagrams of the method for manufacturing the flexible substrate, provided by an embodiment of the present invention.

As illustrated in FIG. 5A, a flexible base 52 is bonded to a support substrate 51 by an adhesive material. The flexible base 52 may be made from PI or PET material. The support substrate 51 may be made from a rigid material such as glass.

As illustrated in FIG. 5B, the TFT technological process and the FPC technological process are completed synchronously to form a TFT structures and a lead structure 53 by adoption of the method for manufacturing the flexible substrate as described above.

As illustrated in FIG. 5C, an upper substrate 54 is bonded to the flexible substrate below to complete a cell assembly and encapsulation process.

As illustrated in FIG. 5D, a flexible backplane is obtained after stripped off from the support substrate.

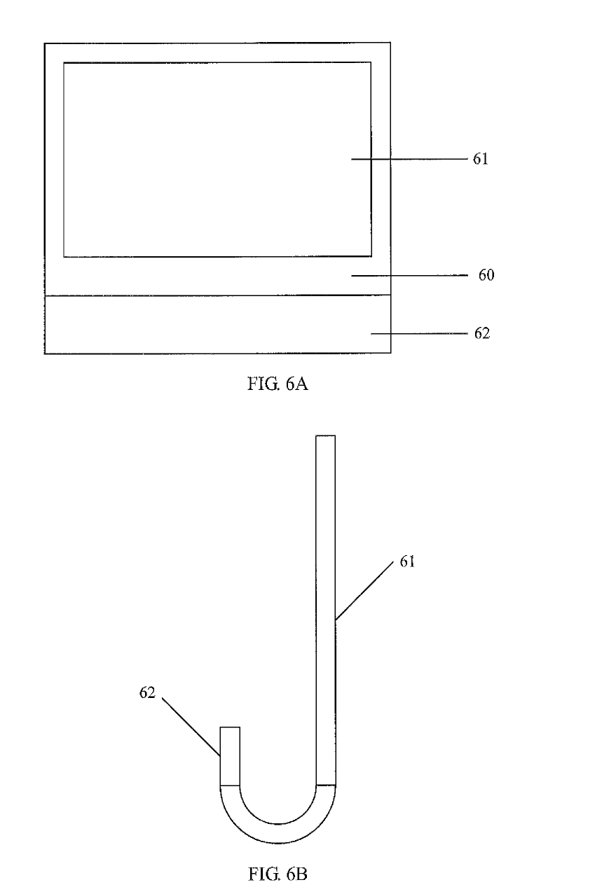

FIGS. 6A and 6B are schematic diagrams of the flexible substrate provided by the embodiment of the present invention. As illustrated in FIG. 6A, a display panel region 61 and an FPC region 62 are formed on the flexible substrate 61. As the substrate is flexible, the FPC region 62 may be disposed at the rear of the display panel region 61, as shown in FIG. 6B, and hence a narrow-frame display device can be manufactured.

At least one embodiment of the present invention provides a flexible display device, which comprises the flexible substrate provided by the above embodiment. The flexible display device provided by an embodiment of the present invention includes but not limited to e-paper display, organic light-emitting diode (OLED) display and polymer dispersed liquid crystal display (PDLCD).

By adoption of the flexible substrate, the manufacturing method thereof and the flexible display device, provided by an embodiment of the present invention, the display panel and the peripheral FPC may be manufactured on the same substrate at the same time without the processes such as the alignment and bonding processes of the FPC and the display panel. Therefore, the manufacturing process is obviously simplified and the manufacturing cost is reduced. Moreover, the manufactured display device has the advantages of light weight, impact resistance and portability.

The foregoing is only the preferred embodiments of the present invention and not intended to limit the scope of protection of the present invention. The scope of protection of the present invention should be defined by the appended claims.

The application claims priority to the Chinese patent application No. 201410242864.4, filed Jun. 3, 2014, the disclosure of which is incorporated herein by reference as part of the application.

1: A flexible substrate, comprising a display panel region and a flexible printed circuit board (FPC) region,
wherein the display panel region includes a flexible base and a gate electrode, a gate insulating layer, an active layer, source/drain electrodes, a passivation layer and a pixel electrode formed on the flexible base; the pixel electrode is electrically connected with the drain electrode through an opening in the passivation layer; and
the FPC region includes a lead structure which is formed on the flexible base and made from a material including at least one or a combination of more selected from a material for preparing the gate electrode, a material for preparing the source/drain electrodes, and a material for preparing the pixel electrode.

2: The flexible substrate according to claim 1, wherein the gate electrode is formed on the flexible base; and
the gate insulating layer is formed on the gate electrode or formed between the gate electrode and the flexible base.

3: The flexible substrate according to claim 2, wherein
where the gate insulating layer is formed on the gate electrode, the active layer is formed on the gate insulating layer; or where the gate insulating layer is formed between the gate electrode and the flexible base, the active layer is formed between the gate insulating layer and the flexible base;
the source/drain electrodes are formed on the active layer or make contact with the bottom of the active layer; and
the passivation layer is formed on the source/drain electrodes.

4: The flexible substrate according to claim 1, wherein the lead structure includes a first conductive layer made from a material for preparing the gate electrode and a second conductive layer made from a material for preparing the source/drain electrodes.

5: The flexible substrate according to claim 4, wherein the lead structure further includes a third conductive layer made from a material for preparing the pixel electrode.

6: The flexible substrate according to claim 1, wherein the lead structure is made from a material including at least one or a combination of more selected from Mo, Fe, Ag, Cu, Al, carbon nanotube and graphene.

7: The flexible substrate according to claim 1, wherein the flexible base is made from polyimide (PI) or polyethylene terephthalate (PET) materials.

8: The flexible substrate according to claim 1, wherein the FPC region is bent at the rear of the display panel region.

9: A method for manufacturing a flexible substrate, comprising:
forming a gate electrode, a gate insulating layer, an active layer, source/drain electrodes, a passivation layer and a pixel electrode of a display panel region on a flexible base, in which the passivation layer is provided with an opening to expose at least one part of the drain electrode, and the pixel electrode is formed on the passivation layer,
wherein a lead structure is formed in the FPC region at the same time when at least one step among the step of forming the gate electrode, the step of forming the source/drain electrodes and the step of forming the pixel electrode is performed.

10: The method according to claim 9, wherein a gate metal layer is formed on the flexible base and patterned to form the gate electrode in the display panel region;
the gate insulating layer and the active layer are formed on the gate electrode in sequence and patterned;
the source/drain electrodes are formed on the active layer; and
the passivation layer is formed on the source/drain electrodes.

11: The method according to claim 9, wherein a first conductive layer of the lead structure is formed in the FPC region at the same time when the gate electrode is formed; and
a second conductive layer of the lead structure is formed at the same time when the source/drain electrodes are formed.

12: The method according to claim 11, further comprising the step of forming a third conductive layer of the lead structure at the same time when the pixel electrode is formed.

13: A flexible display device, comprising the flexible substrate according to claim 1.

14: The flexible substrate according to claim 2, wherein the lead structure includes a first conductive layer made from a material for preparing the gate electrode and a second conductive layer made from a material for preparing the source/drain electrodes.

15: The flexible substrate according to claim 14, wherein the lead structure further includes a third conductive layer made from a material for preparing the pixel electrode.

16: The flexible substrate according to claim 3, wherein the lead structure includes a first conductive layer made from a material for preparing the gate electrode and a second conductive layer made from a material for preparing the source/drain electrodes.

17: The flexible substrate according to claim 16, wherein the lead structure further includes a third conductive layer made from a material for preparing the pixel electrode.

18: The method according to claim 10, wherein a first conductive layer of the lead structure is formed in the FPC region at the same time when the gate electrode is formed; and
a second conductive layer of the lead structure is formed at the same time when the source/drain electrodes are formed.

19: The method according to claim 18, further comprising the step of forming a third conductive layer of the lead structure at the same time when the pixel electrode is formed.
